(19) United States
(12) Patent Application Publication
(10) Pub. No.: US 2025/0133914 A1
(43) Pub. Date: Apr. 24, 2025

(54) DISPLAY DEVICE AND MOTHER SUBSTRATE

(71) Applicant: Japan Display Inc., Tokyo (JP)

(72) Inventors: Ryota TAKASAKI, Tokyo (JP); Naoya IWAHASHI, Tokyo (JP); Sho YANAGISAWA, Tokyo (JP)

(73) Assignee: Japan Display Inc., Tokyo (JP)

(21) Appl. No.: 18/911,261

(22) Filed: Oct. 10, 2024

(30) Foreign Application Priority Data
Oct. 18, 2023 (JP) 2023-179398

(51) Int. Cl. H10K 59/122

(52) U.S. Cl. CPC H10K 59/122

(57) ABSTRACT

According to one embodiment, a display device includes an organic insulating layer provided over a display area and a surrounding area, a lower electrode provided in the display area, an inorganic insulating layer provided on the organic insulating layer, an organic layer provided on the lower electrode, an upper electrode provided on the organic layer, and a plurality of surrounding partitions provided in the surrounding area. The organic insulating layer has a removed portion along an outer edge of a substrate in the surrounding area. The inorganic insulating layer has a loop groove which surrounds the display area in the surrounding area. The surrounding partitions include a pair of first partitions facing each other across the groove.

### CROSS-REFERENCE TO RELATED APPLICATION

This application is based upon and claims the benefit of priority from Japanese Patent Application No. 2023-179398, filed Oct. 18, 2023, the entire contents of which are incorporated herein by reference.

### FIELD

Embodiments described herein relate generally to a display device and a mother substrate.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is the schematic cross-sectional view of the display device DSP along the A-B line of FIG. 2.

FIG. 4 is a diagram for explaining the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a plan view showing an example of a mother substrate 100.

FIG. 11 is a plan view showing a configuration example of the area 100A of the mother substrate 100 shown in FIG. 10.

FIG. 12 is a plan view showing a configuration example of the area 100B shown in FIG. 11.

FIG. 13 is a plan view showing the display panel PNL cut out along the cut lines CL shown in FIG. 12.

FIG. 14 is a cross-sectional view showing a configuration example of the mother substrate 100.

FIG. 15 is a cross-sectional view showing another configuration example of the mother substrate 100.

FIG. 16 is a cross-sectional view showing another configuration example of the mother substrate 100.

FIG. 17 is a cross-sectional view in which an area including a groove 5G is enlarged.

FIG. 18 is a cross-sectional view for explaining a state in which a stacked film FL1 is formed in an area including the removed portion G shown in FIG. 14.

FIG. 19 is a cross-sectional view for explaining a state in which the stacked film FL1 is formed in an area including the groove 5G shown in FIG. 17.

FIG. 20 is a plan view showing another configuration example of the area 100B shown in FIG. 11.

FIG. 21 is a plan view showing the display panel PNL cut out along the cut lines CL shown in FIG. 20.

FIG. 22 is a cross-sectional view showing a configuration example of the mother substrate 100.

FIG. 23 is a cross-sectional view showing another configuration example of the mother substrate 100.

FIG. 24 is a cross-sectional view showing another configuration example of the mother substrate 100.

FIG. 25 is a diagram for explaining problems which could occur when surrounding partitions 9A are not provided.

FIG. 26 is a plan view showing another configuration example of the area 100A of the mother substrate 100 shown in FIG. 10.

FIG. 27 is a plan view showing a configuration example of the area 100B shown in FIG. 26.

FIG. 28 is a plan view showing the display panel PNL cut out along the cut lines CL shown in FIG. 27.

### DETAILED DESCRIPTION

Embodiments described herein aim to provide a display device and a mother substrate such that the reduction in reliability can be prevented.

In general, according to one embodiment, a display device comprises a substrate, an organic insulating layer provided over a display area which displays an image and a surrounding area on an external side relative to the display area above the substrate, a lower electrode provided on the organic insulating layer in the display area, an inorganic insulating layer which is provided on the organic insulating layer and covers a peripheral portion of the lower electrode, an organic layer which is provided on the lower electrode and includes a light emitting layer, an upper electrode provided on the organic layer, and a plurality of surrounding partitions provided in the surrounding area. Each of the surrounding partitions has a first lower portion located on the inorganic insulating layer, and a first upper portion located on the first lower portion and protruding from a side surface of the first lower portion. The organic insulating layer has a removed portion along an outer edge of the substrate in the surrounding area. The inorganic insulating layer has a groove surrounding the display area and formed into a loop shape in the surrounding area. The surrounding partitions include a pair of first partitions facing each other across the groove.

According to another embodiment, a display device comprises a substrate, an organic insulating layer provided over a display area which displays an image and a surrounding area on an external side relative to the display area above the substrate, a lower electrode provided on the organic insulating layer in the display area, an inorganic insulating layer which is provided on the organic insulating layer and covers a peripheral portion of the lower electrode, an organic layer which is provided on the lower electrode and includes a light emitting layer, an upper electrode provided on the organic layer, and a plurality of surrounding partitions provided in the surrounding area. Each of the surrounding partitions has a first lower portion, and a first upper portion located on the first lower portion and protruding from a side surface of the first lower portion. The organic insulating layer has a removed portion along an outer edge of the substrate in the surrounding area. The surrounding partitions include a second partition provided in the removed portion. The second partition is provided along a corner portion in an outer edge of the organic insulating layer and is formed into an L-shape in plan view.

According to yet another embodiment, a display device comprises a substrate, an organic insulating layer provided over a display area which displays an image and a surrounding area on an external side relative to the display area above the substrate, a lower electrode provided on the organic insulating layer in the display area, an inorganic insulating layer which is provided on the organic insulating layer and covers a peripheral portion of the lower electrode, an organic layer which is provided on the lower electrode and includes a light emitting layer, an upper electrode provided on the organic layer, and a plurality of surrounding partitions provided in the surrounding area. Each of the surrounding partitions has a first lower portion, and a first upper portion located on the first lower portion and protruding from a side surface of the first lower portion. The organic insulating layer has a removed portion along an outer edge of the substrate in the surrounding area. An outer edge of the organic insulating layer includes a round corner portion. A radius of curvature of the round corner portion is greater than or equal to a width of the removed portion.

According to yet another embodiment, a mother substrate comprises a panel portion which has a display area displaying an image, and a surrounding area on an external side relative to the display area, a margin portion on an external side relative to the panel portion, an organic insulating layer provided over the panel portion and the margin portion, a lower electrode provided on the organic insulating layer in the display area, an inorganic insulating layer which is provided on the organic insulating layer and covers a peripheral portion of the lower electrode, an organic layer which is provided on the lower electrode and includes a light emitting layer, an upper electrode provided on the organic layer, and a plurality of surrounding partitions provided in the surrounding area. Each of the surrounding partitions has a first lower portion located on the inorganic insulating layer and a first upper portion located on the first lower portion and protruding from a side surface of the first lower portion. The inorganic insulating layer has a first groove surrounding the display area and formed into a loop shape in the surrounding area. The surrounding partitions include a pair of first partitions facing each other across the first groove.

According to yet another embodiment, a mother substrate comprises a panel portion which has a display area displaying an image, and a surrounding area on an external side relative to the display area, a margin portion on an external side relative to the panel portion, an organic insulating layer provided over the panel portion and the margin portion, a lower electrode provided on the organic insulating layer in the display area, an inorganic insulating layer which is provided on the organic insulating layer and covers a peripheral portion of the lower electrode, an organic layer which is provided on the lower electrode and includes a light emitting layer, an upper electrode provided on the organic layer, and a plurality of surrounding partitions provided in the surrounding area. Each of the surrounding partitions has a first lower portion located on the inorganic insulating layer and a first upper portion located on the first lower portion and protruding from a side surface of the first lower portion. The organic insulating layer has a removed portion along an outer shape of the panel portion. The surrounding partitions include a second partition provided in the removed portion. The second partition is provided along a corner portion in an outer edge of the organic insulating layer and is formed into an L-shape in plan view.

According to yet another embodiment, a mother substrate comprises a panel portion which has a display area displaying an image, and a surrounding area on an external side relative to the display area, a margin portion on an external side relative to the panel portion, an organic insulating layer provided over the panel portion and the margin portion, a lower electrode provided on the organic insulating layer in the display area, an inorganic insulating layer which is provided on the organic insulating layer and covers a peripheral portion of the lower electrode, an organic layer which is provided on the lower electrode and includes a light emitting layer, an upper electrode provided on the organic layer, and a plurality of surrounding partitions provided in the surrounding area. Each of the surrounding partitions has a first lower portion located on the inorganic insulating layer and a first upper portion located on the first lower portion and protruding from a side surface of the first lower portion. The organic insulating layer has a removed portion along an outer shape of the panel portion. An outer edge of the organic insulating layer includes a round corner portion. A radius of curvature of the round corner portion is greater than or equal to ½ of a width of the removed portion.

The embodiments can provide a display device and a mother substrate such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

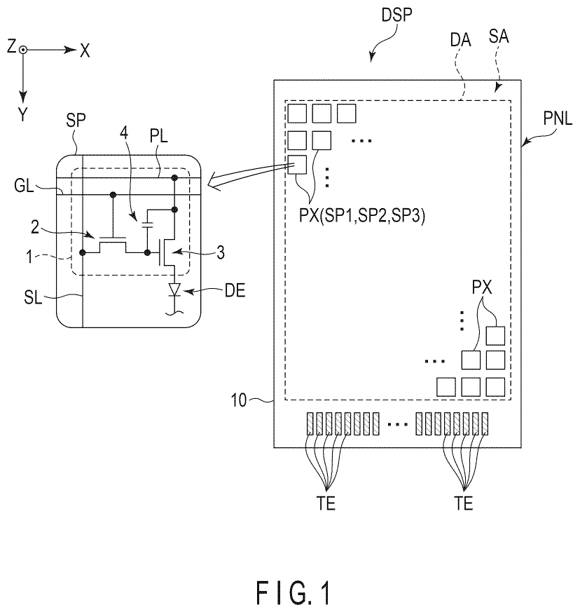

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and the drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element DE.

It should be noted that the configuration of the pixel circuit 1 is not limited to the example shown in the figure. For example, the pixel circuit 1 may comprise more thin-film transistors and capacitors.

The display element DE is an organic light emitting diode (OLED) as a light emitting element, and may be called an organic EL element.

The surrounding area SA comprises a plurality of terminals TE which are arranged along one direction. In the example shown in the figure, the terminals TE are arranged in the first direction X. Each of the terminals TE extends in the second direction Y. However, the configuration is not limited to this example. For example, some of the terminals TE may extend in an oblique direction. For example, these terminals TE are electrically connected to a flexible printed circuit or an IC chip.

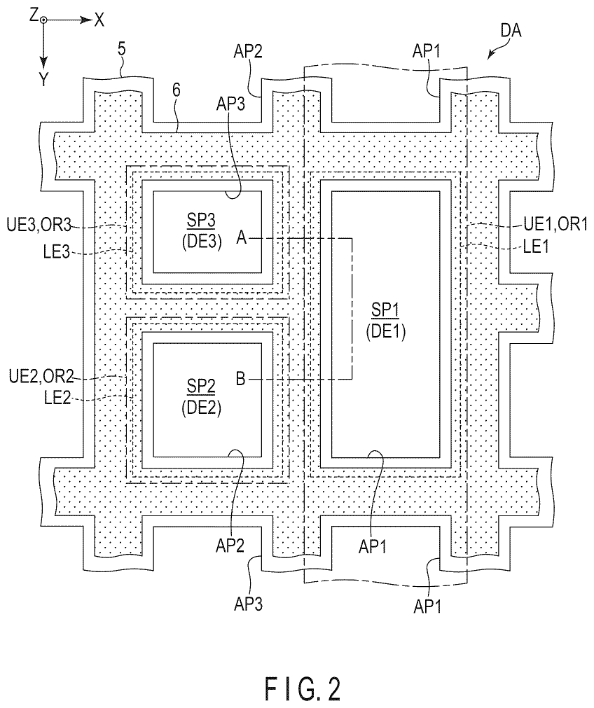

FIG. 2 is a diagram showing an example of the layout of subpixels SP1, SP2 and SP3.

In the example shown in the figure, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 has apertures AP1, AP2 and AP3 in subpixels SP1, SP2 and SP3, respectively. The inorganic insulating layer 5 having these apertures AP1, AP2 and AP3 may be called a rib.

The partition 6 overlaps the inorganic insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the inorganic insulating layer 5. The partition 6 is conductive and is electrically connected to, of the terminals TE shown in FIG. 1, each terminal TE having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The lower electrode LE1, the organic layer OR1 and the upper electrode UE1 are surrounded by the partition 6 in plan view. The peripheral portion of each of the organic layer OR1 and the upper electrode UE1 overlaps the inorganic insulating layer 5 in plan view. The organic layer OR1 includes a light emitting layer which emits light in, for example, a blue wavelength range.

The display element DE2 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The lower electrode LE2, the organic layer OR2 and the upper electrode UE2 are surrounded by the partition 6 in plan view. The peripheral portion of each of the organic layer OR2 and the upper electrode UE2 overlaps the inorganic insulating layer 5 in plan view. The organic layer OR2 includes a light emitting layer which emits light in, for example, a green wavelength range.

The display element DE3 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The lower electrode LE3, the organic layer OR3 and the upper electrode UE3 are surrounded by the partition 6 in plan view. The peripheral portion of each of the organic layer OR3 and the upper electrode UE3 overlaps the inorganic insulating layer 5 in plan view. The organic layer OR3 includes a light emitting layer which emits light in, for example, a red wavelength range.

In the example shown in the figure, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, the organic layers and the upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

The lower electrode LE1 is electrically connected to the pixel circuit 1 (see FIG. 1) of subpixel SP1. The lower electrode LE2 is electrically connected to the pixel circuit 1 of subpixel SP2. The lower electrode LE3 is electrically connected to the pixel circuit 1 of subpixel SP3.

In the example shown in the figure, the area of the aperture AP1, the area of the aperture AP2 and the area of the aperture AP3 are different from each other. The area of the aperture AP1 is greater than that of the aperture AP2, and the area of the aperture

AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

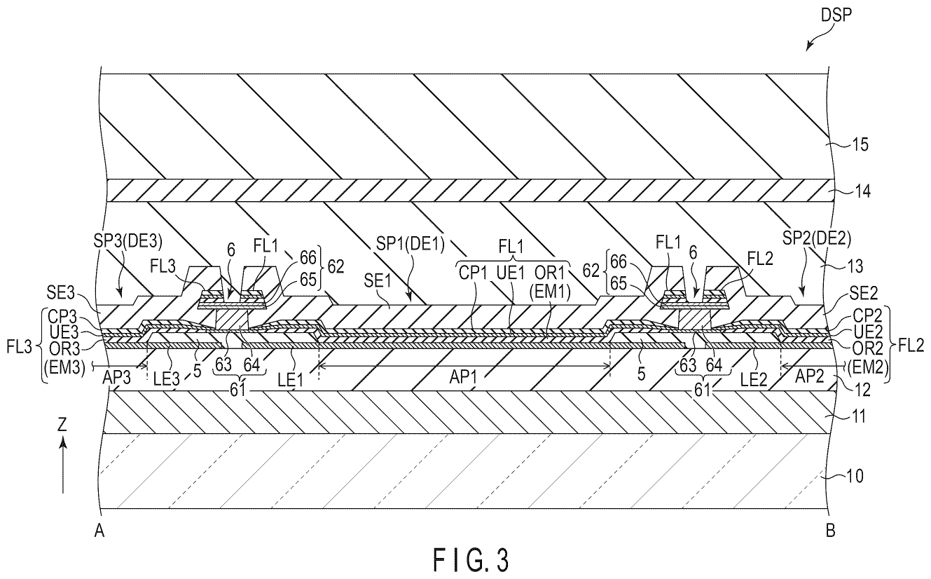

FIG. 3 is the schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The lower electrodes LE1, LE2 and LE3 are connected to the pixel circuits 1 of subpixels SP1, SP2 and SP3, respectively, through contact holes provided in the insulating layer 12. It should be noted that the contact holes of the insulating layer 12 are omitted in FIG. 3.

The partition 6 includes a conductive lower portion 61 provided on the inorganic insulating layer 5, and an upper portion 62 provided on the lower portion 61. The upper portion 62 has a width greater than that of the lower portion 61. The both end portions of the upper portion 62 protrude relative to the side surfaces of the lower portion 61. This shape of the partition 6 is called an overhang shape. In the example shown in the figure, the lower

portion 61 has a first conductive layer 63 provided on the inorganic insulating layer 5 and a second conductive layer 64 provided on the first conductive layer 63. For example, the first conductive layer 63 is formed so as to be thinner than the second conductive layer 64. In the example shown in the figure, the both end portions of the first conductive layer 63 protrude from the side surfaces of the second conductive layer 64.

The upper portion 62 has a first thin film 65 provided on the second conductive layer 64 and a second thin film 66 provided on the first thin film 65. The both end portions of the first thin film 65 and the second thin film 66 protrude from the side surfaces of the second conductive layer 64.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example shown in the figure, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively. It should be noted that the cap layers CP1, CP2 and CP3 may be omitted.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example shown in the figure, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element DE1).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element DE2).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element DE3).

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The end portions of the sealing layers SE1, SE2 and SE3 and the end portions of the stacked films FL1, FL2 and FL3 are located on the partition 6. In the example shown in the figure, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The partition 6 and the sealing layers SE1, SE2 and SE3 are covered with a resin layer 13. The resin layer 13 is covered with a sealing layer 14. The sealing layer 14 is covered with a resin layer 15.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The first conductive layer 63 is formed of, for example, a titanium-based material such as titanium or a titanium compound. The second conductive layer 64 is formed of a material which is different from the first conductive layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material which is different from that of the lower portion 61. The first thin film 65 is formed of, for example, a titanium-based material such as titanium or a titanium compound. The second thin film 66 is formed of, for example, an oxide conductive material such as indium tin oxide (ITO).

Each of the lower electrodes LE1, LE2 and LE3 is, for example, a multilayer body including a transparent layer formed of an oxide conductive material such as indium tin oxide (ITO) and a reflective layer formed of a metal material such as silver. For example, each of the lower electrodes LE1, LE2 and LE3 is a multilayer body including a reflective layer between a pair of transparent layers. The lower transparent layer functions as an adhesive layer which adheres tightly to the insulating layer 12.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, the insulating layer 12 and the inorganic insulating layer 5 shown in the figure are provided over the display area DA and the surrounding area SA.

Now, this specification explains the manufacturing method of the display device DSP. Regarding each figure for explaining the manufacturing method, the illustration of the lower side of the insulating layer 12 is omitted.

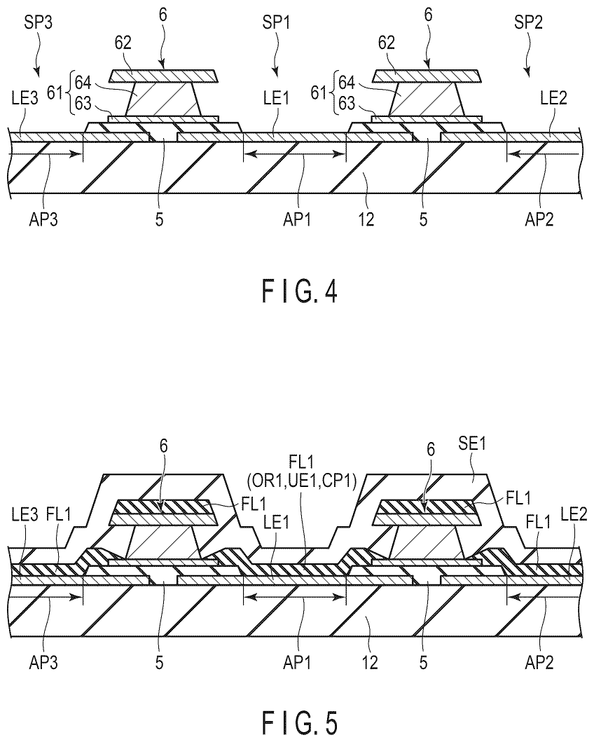

First, the circuit layer 11 and the insulating layer 12 are formed over the display area DA and the surrounding area SA on the substrate 10. Subsequently, as shown in FIG. 4, the lower electrode LE1 of subpixel SP1, the lower electrode LE2 of subpixel SP2 and the lower electrode LE3 of subpixel SP3 are formed on the insulating layer 12.

Subsequently, the inorganic insulating layer 5 which covers the peripheral portions of the lower electrodes LE1, LE2 and LE3 is formed. The inorganic insulating layer 5 is formed of silicon oxide, silicon nitride, silicon oxynitride, etc.

Subsequently, the partition 6 which has the lower portion 61 located on the inorganic insulating layer 5 and the upper portion 62 located on the lower portion 61 is formed. The first conductive layer 63 of the lower portion 61 and the upper portion 62 protrude from the side surfaces of the second conductive layer 64 of the lower portion 61. The first conductive layer 63 is formed of a conductive material such as a titanium-based material, and the second conductive layer 64 is formed of a conductive material such as an aluminum-based material.

It should be noted that the process of forming the apertures AP1, AP2 and AP3 in the inorganic insulating layer 5 may be performed either before the partition 6 is formed or after the partition 6 is formed.

Subsequently, the display element DE1 is formed.

First, as shown in FIG. 5, the stacked film FL1 including the organic layer OR1, the upper electrode UE1 and the cap layer CP1 is formed. The process of forming the stacked film FL1 includes the process of forming the organic layer OR1 which is in contact with the lower electrode LE1 in the aperture AP1, the process of forming the upper electrode UE1 which covers the organic layer OR1 and is in contact with the lower portion 61 of the partition 6, and the process of forming the cap layer CP1 located on the upper electrode UE1. The process of forming the organic layer OR1 includes the process of forming each of the hole injection layer, the hole transport layer, the electron blocking layer, the light emitting layer, the hole blocking layer, the electron transport layer, the electron injection layer and the like. Each of the organic layer OR1, the upper electrode UE1 and the cap layer CP1 is formed by vapor deposition using the partition 6 as a mask. The stacked film FL1 is divided into a plurality of portions by the partition 6 having the overhang shape. These organic layer OR1, upper electrode UE1 and cap layer CP1 are continuously formed while maintaining a vacuum environment.

Subsequently, the sealing layer SE1 is formed on the stacked film FL1 by depositing an inorganic insulating material. The sealing layer SE1 is formed by chemical vapor deposition (CVD). The sealing layer SE1 continuously covers the portions into which the stacked film FL1 is divided, and the partition 6.

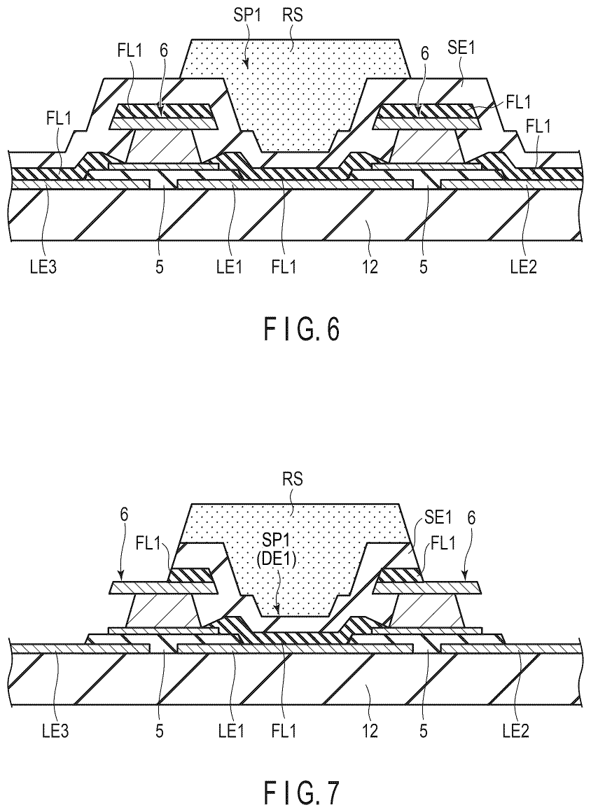

Subsequently, as shown in FIG. 6, a resist RS patterned into a predetermined shape is formed on the sealing layer SE1. The resist RS overlaps subpixel SP1 and part of the partition 6 around subpixel SP1.

Subsequently, as shown in FIG. 7, the sealing layer SE1 and the stacked film FL1 exposed from the resist RS are removed in series by performing etching using the resist RS as a mask. In this etching, the sealing layer SE1 exposed from the resist RS is removed. Subsequently, the cap layer CP1 exposed from the sealing layer SE1 is removed. Further, the upper electrode UE1 exposed from the cap layer CP1 is removed. Subsequently, the organic layer OR1 exposed from the upper electrode UE1 is removed. In this manner, the lower electrode LE2 of subpixel SP2 and the lower electrode LE3 of subpixel SP3 are exposed.

Subsequently, the resist RS is removed. By this process, the display element DE1 is formed in subpixel SP1.

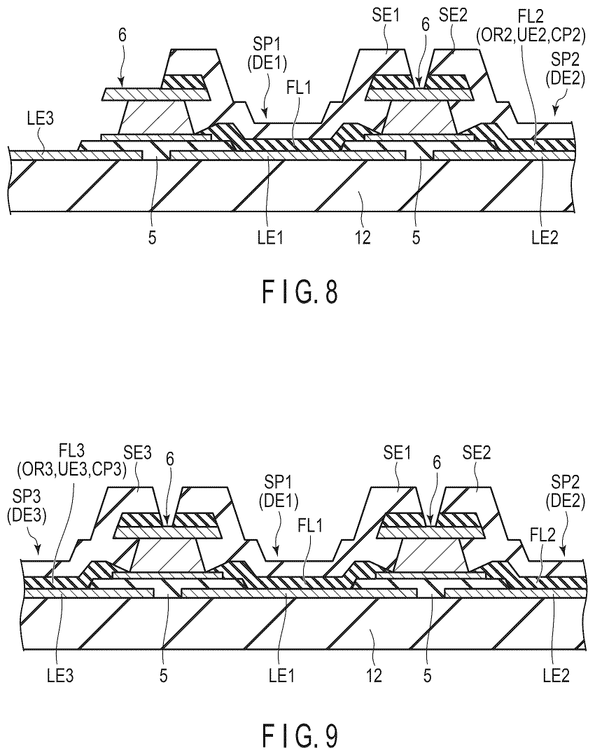

Subsequently, as shown in FIG. 8, the display element DE2 is formed. The procedure of forming the display element DE2 is similar to that of forming the display element DE1. Specifically, the stacked film FL2 is formed by forming the organic layer OR2 including the light emitting layer EM2, the upper electrode UE2 and the cap layer CP2 in order on the lower electrode LE2. Subsequently, the sealing layer SE2 is formed on the stacked film FL2. Subsequently, a resist is formed on the sealing layer SE2. The sealing layer SE2, the cap layer CP2, the upper electrode UE2 and the organic layer OR2 are patterned by etching using the resist as a mask. After this patterning, the resist is removed. In this manner, the display element DE2 is formed in subpixel SP2, and the lower electrode LE3 of subpixel SP3 is exposed.

Subsequently, as shown in FIG. 9, the display element DE3 is formed. The procedure of forming the display element DE3 is similar to that of forming the display element DE1. Specifically, the stacked film FL3 is formed by forming the organic layer OR3 including the light emitting layer EM3, the upper electrode UE3 and the cap layer CP3 in order on the lower electrode LE3. Subsequently, the sealing layer SE3 is formed on the stacked film FL3. Subsequently, a resist is formed on the sealing layer SE3. The sealing layer SE3, the cap layer CP3, the upper electrode UE3 and the organic layer OR3 are patterned by etching using the resist as a mask. After this patterning, the resist is removed. By this process, the display element DE3 is formed in subpixel SP3.

Subsequently, the resin layer 13, the sealing layer 14 and the resin layer 15 shown in FIG. 3 are formed in order. By this process, the display device DSP is completed.

In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

Now, this specification explains a mother substrate 100 for a display device (hereinafter, simply referred to as a mother substrate 100) for manufacturing a plurality of display devices DSP in a lump.

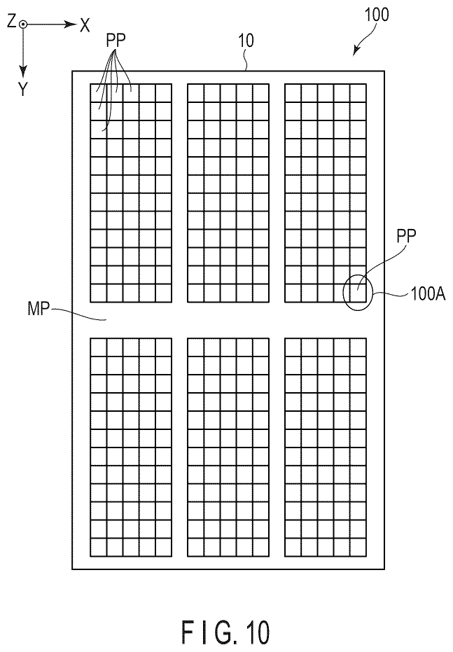

FIG. 10 is a plan view showing an example of the mother substrate 100.

The mother substrate 100 comprises a plurality of panel portions PP and a margin portion MP provided on an external side relative to these panel portions PP on a large substrate 10. The large substrate 10 is formed into, for example, a rectangular shape. The panel portions PP are arrayed in matrix in the first direction X and the second direction Y. The panel portions PP are extracted by dividing the mother substrate 100 along cut lines. Each of the extracted panel portions PP corresponds to the display panel PNL shown in FIG. 1.

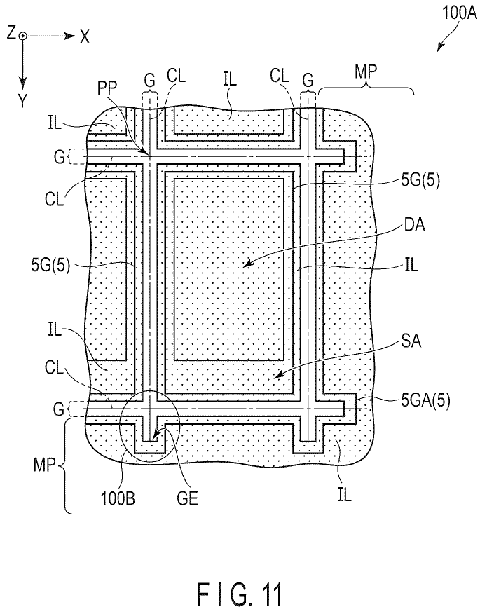

FIG. 11 is a plan view showing a configuration example of the area 100A of the mother substrate 100 shown in FIG. 10.

The area 100A includes one panel portion PP. The cut lines CL shown by one-dot chain lines in the figure extend in, for example, the first direction X and the second direction Y. These cut lines CL could be the outer shape of the display panel PNL shown in FIG. 1. Each of the panel portions PP comprises the display area DA and the surrounding area SA.

An organic insulating layer IL includes at least the insulating layer 12 shown in FIG. 3. The organic insulating layer IL is provided in each of the panel portions PP and is also provided in the margin portion MP. The organic insulating layer IL has a removed portion G along the outer shape of each panel portion PP. The cut lines CL overlap the removed portion G. The removed portion G is an area which penetrates the organic insulating layer IL such that the base is exposed, and is formed as a groove having grating shape which surrounds each panel portion PP. In the example shown in the figure, the removed portion G extends in the first direction X and the second direction Y. The removed portion G has an end portion GE located in the margin portion MP.

When one panel portion PP is particularly looked at, the removed portion G is formed into a loop shape surrounding the panel portion PP. In each panel portion PP, the display area DA overlaps the island-shaped organic insulating layer IL. Part of the surrounding area SA also overlaps the organic insulating layer IL.

The inorganic insulating layer 5 has a loop groove (first groove) 5G which surrounds the display area DA in the surrounding area SA of the panel portion PP. The groove 5G is formed between the display area DA and the removed portion G. The inorganic insulating layer 5 has a groove (second groove) 5GA which surrounds the end portion GE of the removed portion G in the margin portion MP. The groove 5G and the groove 5GA are areas which penetrate the inorganic insulating layer 5 such that the base (organic insulating layer IL) is exposed. The removed portion G of the organic insulating layer IL is located between the groove 5G and the groove 5GA.

In the inorganic insulating layer 5, the portion which overlaps the display area DA is spaced apart from the portion located between the groove 5G and the removed portion G or the portion located between the groove 5G and the groove 5GA. In the inorganic insulating layer 5, the portion located between the groove 5G and the groove 5GA is spaced apart from the portion located on an external side relative to the groove 5GA.

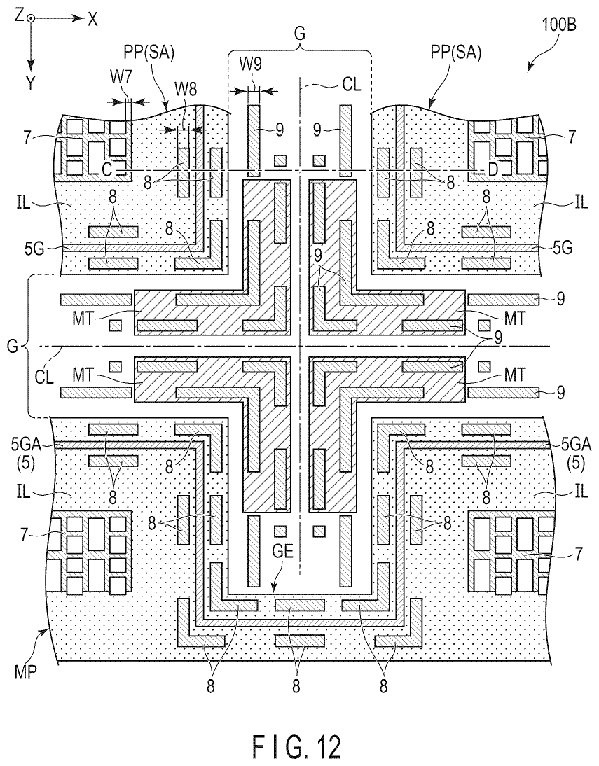

FIG. 12 is a plan view showing a configuration example of the area 100B shown in FIG. 11.

The area 100B includes the intersection of the cut line CL extending in the first direction X and the cut line CL extending in the second direction Y.

Metal layers MT are provided in the removed portion G. At the intersection, four metal layers MT are spaced apart from each other, and each of the metal layers MT is formed into an L-shape along the cut lines CL. The cut line CL extending in the first direction X is located between two metal layers MT which are adjacent to each other in the second direction Y. The cut line CL extending in the second direction Y is located between two metal layers MT which are adjacent to each other in the first direction X. A cruciform space is defined such that it is surrounded by the four metal layers MT. These four metal layers MT function as, for example, alignment marks for the alignment of the mother substrate 100.

Surrounding partitions 7, 8 and 9 are provided in the surrounding area SA of each panel portion PP and the margin portion MP and are spaced apart from each other. The surrounding partitions 7 and 8 overlap the organic insulating layer IL, and the surrounding partitions 9 overlap the removed portion G, in plan view. Although details are omitted here, each of these surrounding partitions 7, 8 and 9 has a cross-sectional shape similar to that of the partition 6 of the display area DA, and has a lower portion and an upper portion located on the lower portion and protruding from the side surfaces of the lower portion.

Each of the surrounding partitions 7 is formed into a grating shape. For example, each surrounding partition 7 is formed with a pattern similar to that of the grating-shaped partition 6 shown in FIG. 2.

A plurality of surrounding partitions (first partitions) 8 are located between each surrounding partition 7 and the removed portion G and are provided along the groove 5G. For example, the surrounding partitions 8 include a pair of surrounding partitions 8 extending in the first direction X and arranged in the second direction Y. The pair of surrounding partitions 8 arranged in the second direction Y in this manner face each other across the groove 5G extending in the first direction X. Further, the plurality of surrounding partitions 8 include a pair of surrounding partitions 8 extending in the second direction Y and arranged in the first direction X. The pair of surrounding partitions 8 arranged in the first direction X in this manner face each other across the groove 5G extending in the second direction Y. In addition, the plurality of surrounding partitions 8 include an L-shaped surrounding partition 8 provided along the corner portion of the groove 5G.

A plurality of surrounding partitions (second partitions) 9 are provided in the removed portion G. In the removed portion G, the surrounding partitions 9 are provided along the cut lines CL. For example, the plurality of surrounding partitions 9 include surrounding partitions 9 extending in the first direction X. These surrounding partitions 9 are provided along the cut line CL extending in the first direction X. Further, the plurality of surrounding partitions 9 include surrounding partitions 9 extending in the second direction Y. These surrounding partitions 9 are provided along the cut line CL extending in the second direction Y. Moreover, the plurality of surrounding partitions 9 include L-shaped surrounding partitions 9 provided along the intersection of the cut lines CL. The surrounding partitions 9 located at the intersection overlap the metal layers MT in plan view. To prevent false recognition of the alignment marks, it is preferable that the surrounding partitions 9 overlapping the metal layers MT should not extend to areas in which the metal layers MT are not present. In the removed portion G, to prevent a cut failure, the metal layers MT and the surrounding partitions 9 are provided so as not to overlap the cut lines CL.

To prevent the loss of the surrounding partitions 9 caused by excessively removing the surrounding partitions 9 provided in the removed portion G in wet etching at the time of forming the surrounding partitions 7, 8 and 9, width W9 of each surrounding partition 9 provided in the removed portion G should be preferably greater than width W7 of each surrounding partition 7 provided above the organic insulating layer IL. In the example shown in the figure, width W8 of each surrounding partition 8 is greater than width W7. However, width W8 may be equal to width W7.

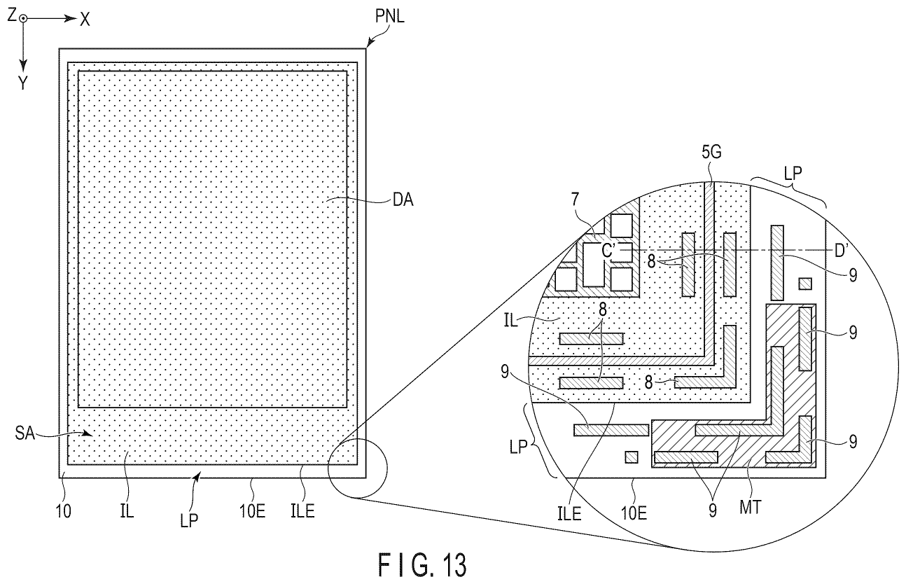

FIG. 13 is a plan view showing the display panel PNL cut out along the cut lines CL shown in FIG. 12.

The cut lines CL shown in FIG. 12 correspond to the outer edge 10E of the substrate 10. However, in a case where the mother substrate 100 is cut along the cut lines CL, and subsequently, the extracted panel portion is further cut to be formed into the desired shape, the position of at least part of the outer edge 10E is different from the position of the cut lines CL shown in FIG. 12.

The organic insulating layer IL is provided over the display area DA and the surrounding area SA. The organic insulating layer IL has a removed portion LP along the outer edge 10E in the surrounding area SA. In the example shown in the figure, the removed portion LP is formed into a loop shape and formed along the whole circumference of the outer edge 10E. The removed portion LP corresponds to part of the removed portion G shown in FIG. 12.

The outer edge ILE of the organic insulating layer IL does not overlap the outer edge 10E of the substrate 10 and is located between the outer edge 10E and the display area DA in plan view.

When one corner portion of the substrate 10 is enlarged, part of the metal layers MT constituting the alignment marks shown in FIG. 12 and the surrounding partitions 9 are provided in the removed portion LP. In other words, the metal layer MT and the surrounding partitions 9 are located between the outer edge ILE and the outer edge 10E in plan view. The metal layer MT is formed into an L-shape along the corner portion of the substrate 10. Some of the surrounding partitions 9 overlapping the metal layer MT are linearly formed along the outer edge 10E. The other surrounding partitions 9 overlapping the metal layer MT are formed into an L-shape along the corner portion of the substrate 10.

The surrounding partition 7 overlapping the organic insulating layer IL in the surrounding area SA is formed into a grating shape in plan view. Regarding, of the surrounding partitions 8 overlapping the organic insulating layer IL, each pair of surrounding partitions 8 arranged across an gap, the surrounding partitions 8 face each other across the groove 5G.

Now, this specification explains several configuration examples of the sectional structure of the mother substrate 100 along the C-D line of FIG. 12.

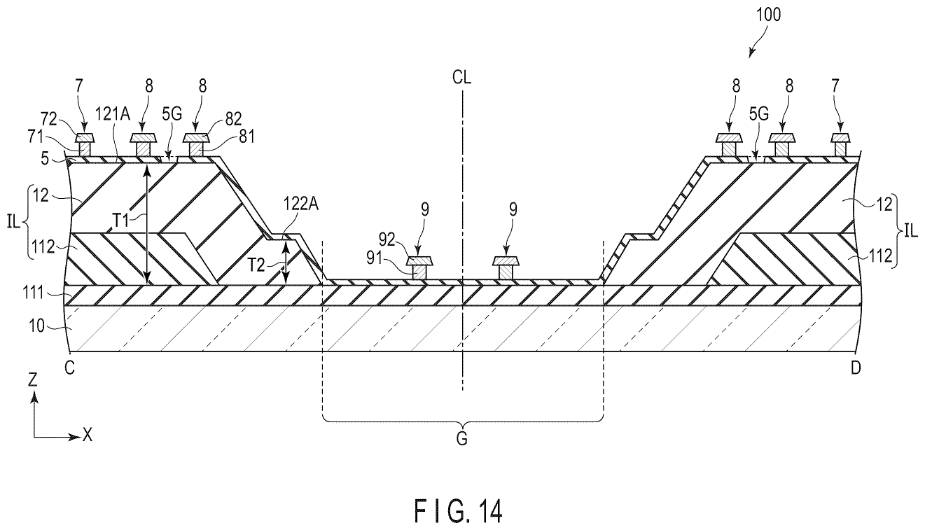

FIG. 14 is a cross-sectional view showing a configuration example of the mother substrate 100.

An insulating layer 111 is an inorganic insulating layer and is provided on the substrate 10. An insulating layer 112 is an organic insulating layer and is provided on the insulating layer 111. These insulating layer 111 and insulating layer 112 are included in the circuit layer 11 shown in FIG. 3. It should be noted that the insulating layer 111 may be omitted. Another insulating layer or conductive layer may be provided between the substrate 10 and the insulating layer 111. The metal layers MT shown in FIG. 12 are provided between the substrate 10 and the insulating layer 111.

The insulating layer 12 is an organic insulating layer, covers the insulating layer 112 and has the removed portion G in the area which is in contact with the insulating layer 111. In the configuration example shown in FIG. 14, the organic insulating layer IL described above has the insulating layer 112 and the insulating layer 12. When this specification focuses attention on the cross sectional shape of this organic insulating layer IL, the organic insulating layer IL has a stepwise cross section in which the thickness decreases toward the removed portion G.

Thickness T1 of the organic insulating layer IL is the sum of the thickness of the insulating layer 112 and the thickness of the insulating layer 12 and corresponds to the length from the upper surface of the insulating layer 111 to substantially a flat upper surface 121A of the insulating layer 12 in the third direction Z.

Thickness T2 of the organic insulating layer IL is the thickness of the insulating layer 12 and corresponds to the length from the upper surface of the insulating layer 111 to substantially a flat upper surface 122A of the insulating layer 12 in the third direction Z. Thickness T2 is less than thickness T1. The upper surface 122A is located between the upper surface 121A and the removed portion G and is located on the lower side than the upper surface 121A.

The inorganic insulating layer 5 covers the insulating layer 12 and covers the insulating layer 111 in the removed portion G. The groove 5G penetrates the inorganic insulating layer 5 such that the upper surface 121A of the insulating layer 12 is exposed. The groove 5G can be formed by, for example, the same process as the aperture AP1 etc., shown in FIG. 2 etc.

The surrounding partitions 7 and 8 are provided above the organic insulating layer IL, and the surrounding partitions 9 are provided in the removed portion G. In the example shown in the figure, the surrounding partitions 7 and 8 are provided above the upper surface 121A while they are not provided above the upper surface 122A. However, the surrounding partitions 7 and 8 may be provided above the upper surface 122A.

Each surrounding partition 7 has a lower portion 71 provided on the inorganic insulating layer 5 and an upper portion 72 provided on the lower portion 71. The upper portion 72 has a width which is greater than that of the lower portion 71. The both end portions of the upper portion 72 protrude relative to the side surfaces of the lower portion 71.

Each surrounding partition 8 has a lower portion 81 provided on the inorganic insulating layer 5 and an upper portion 82 provided on the lower portion 81. The upper portion 82 has a width which is greater than that of the lower portion 81. The both end portions of the upper portion 82 protrude relative to the side surfaces of the lower portion 81.

Each surrounding partition 9 has a lower portion 91 provided on the inorganic insulating layer 5 and an upper portion 92 provided on the lower portion 91. The upper portion 92 has a width which is greater than that of the lower portion 91. The both end portions of the upper portion 92 protrude relative to the side surfaces of the lower portion 91.

Thus, each of the surrounding partitions 7, 8 and 9 has an overhang shape similar to that of the partition 6 shown in FIG. 3. The surrounding partitions 7, 8 and 9 can be formed by the same process as the partition 6. In this case, the lower portions 71, 81 and 91 are formed of the same material as the lower portion 61. The upper portions 72, 82 and 92 are formed of the same material as the upper portion 62.

The organic insulating layer IL having a stepwise cross section can be formed by, for example, the following method.

First, the insulating layer 112 is formed on the insulating layer 111. Subsequently, the insulating layer 12 having the removed portion G, the upper surface 121A and the upper surface 122A is formed. This insulating layer 12 can be formed by, for example, the following method.

Specifically, for example, an insulating layer is formed by using a positive organic material on the whole surface of the mother substrate 100 in which the insulating layer 112 is formed. Subsequently, the insulating layer is exposed to light. In this exposure process, the amount of exposure of the removed portion G is set so as to be the maximum value, and the amount of exposure is set so as to decrease in stages from the removed portion G toward the external side. Subsequently, the exposed insulating layer is developed. Subsequently, the insulating layer is baked.

By this process, the organic insulating layer IL having the cross sectional shape described above is formed. At this time, the removed portion G is formed into a loop shape surrounding the display area DA or each panel portion PP as shown in FIG. 11 etc.

In this configuration example, when the mother substrate 100 is cut along the cut lines CL, the cross section of the display panel PNL along the C′-D′ line of FIG. 13 corresponds to the cross section of the area on the left side relative to the cut line CL in the mother substrate 100 shown in FIG. 14.

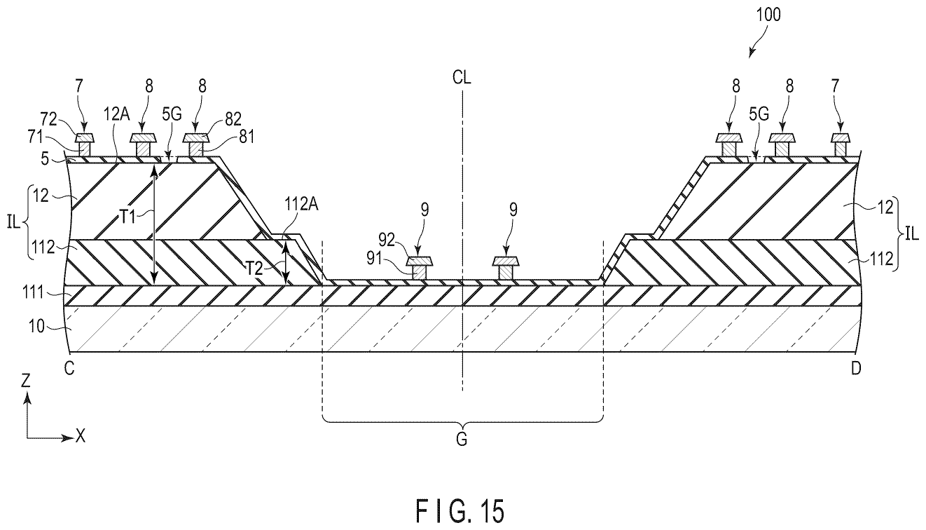

FIG. 15 is a cross-sectional view showing another configuration example of the mother substrate 100.

The configuration example shown in FIG. 15 is different from that shown in FIG. 14 in respect that the insulating layer 112 extends toward the cut line CL relative to the insulating layer 12. The insulating layer 112 has the removed portion G. The insulating layer 12 is provided on the insulating layer 112. When this specification focuses attention on the cross sectional shape of the organic insulating layer IL having the insulating layer 112 and the insulating layer 12, the organic insulating layer IL has a stepwise cross section in which the thickness decreases toward the removed portion G.

Thickness T1 of the organic insulating layer IL is the sum of the thickness of the insulating layer 112 and the thickness of the insulating layer 12 and corresponds to the length from the upper surface of the insulating layer 111 to substantially the flat upper surface 12A of the insulating layer 12 in the third direction Z.

Thickness T2 of the organic insulating layer IL is the thickness of the insulating layer 112 exposed from the insulating layer 12 and corresponds to the length from the upper surface of the insulating layer 111 to substantially the flat upper surface 112A of the insulating layer 112 in the third direction Z. Thickness T2 is less than thickness T1. The upper surface 112A is located between the upper surface 12A and the removed portion G and is located on the lower side than the upper surface 12A.

The inorganic insulating layer 5 covers the insulating layer 12, covers the insulating layer 112 exposed from the insulating layer 12 and covers the insulating layer 111 in the removed portion G. The groove 5G penetrates the inorganic insulating layer 5 such that the upper surface 12A of the insulating layer 12 is exposed.

The surrounding partitions 7 and 8 are provided above the organic insulating layer IL, and the surrounding partitions 9 are provided in the removed portion G. In the example shown in the figure, the surrounding partitions 7 and 8 are provided above the upper surface 12A while they are not provided above the upper surface 112A. However, the surrounding partitions 7 and 8 may be provided above the upper surface 112A. All of the respective lower portions 71, 81 and 91 of the surrounding partitions 7, 8 and 9 are provided on the inorganic insulating layer 5.

The organic insulating layer IL having a stepwise cross section can be formed by, for example, the following method.

First, the insulating layer 112 having the removed portion G and the upper surface 112A is formed on the insulating layer 111. Subsequently, the insulating layer 12 having the upper surface 12A is formed on the insulating layer 112. At this time, the insulating layer 12 is formed such that part of the insulating layer 112 is exposed near the removed portion G.

By this process, the organic insulating layer IL having the cross sectional shape described above is formed.

In this configuration example, when the mother substrate 100 is cut along the cut lines CL, the cross section of the display panel PNL along the C′-D′ line of FIG. 13 corresponds to the cross section of the area on the left side relative to the cut line CL in the mother substrate 100 shown in FIG. 15.

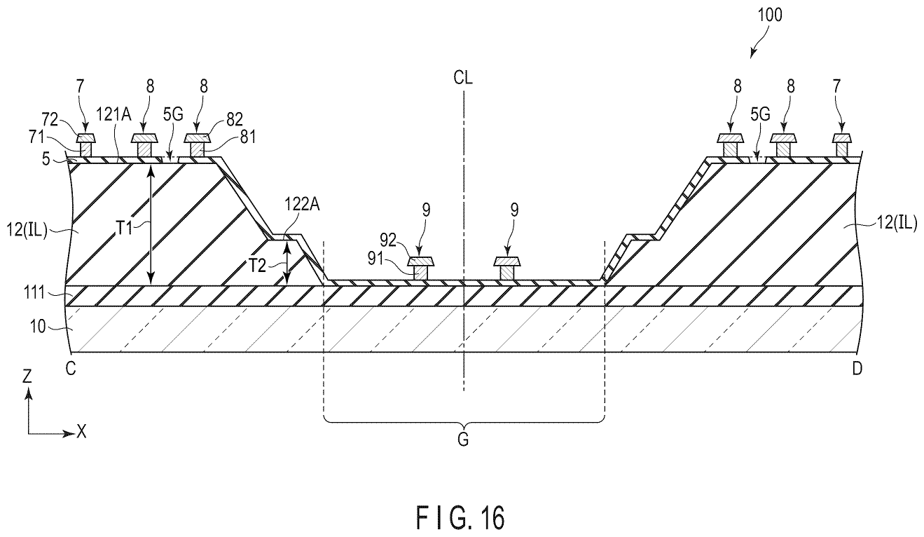

FIG. 16 is a cross-sectional view showing another configuration example of the mother substrate 100.

The configuration example shown in FIG. 16 is different from that shown in FIG. 14 in respect that the organic insulating layer IL having a stepwise cross section is a single-layer body of the insulating layer 12. The insulating layer 112 does not exist. The insulating layer 12 is provided on the insulating layer 111 and has the removed portion G. When this specification focuses attention on the cross sectional shape of the organic insulating layer IL, the organic insulating layer IL has a stepwise cross section in which the thickness decreases toward the removed portion G.

Thickness T1 of the organic insulating layer IL corresponds to the length from the upper surface of the insulating layer 111 to substantially a flat upper surface 121A of the insulating layer 12 in the third direction Z. Thickness T2 of the organic insulating layer IL corresponds to the length from the upper surface of the insulating layer 111 to substantially a flat upper surface 122A of the insulating layer 12 in the third direction Z. Thickness T2 is less than thickness T1. The upper surface 122A is located between the upper surface 121A and the removed portion G and is located on the lower side than the upper surface 121A.

The inorganic insulating layer 5 covers the insulating layer 12 and covers the insulating layer 111 in the removed portion G. The groove 5G penetrates the inorganic insulating layer 5 such that the upper surface 121A of the insulating layer 12 is exposed.

The surrounding partitions 7 and 8 are provided above the organic insulating layer IL, and the surrounding partitions 9 are provided in the removed portion G. In the example shown in the figure, the surrounding partitions 7 and 8 are provided above the upper surface 121A while they are not provided above the upper surface 122A. However, the surrounding partitions 7 and 8 may be provided above the upper surface 122A. All of the respective lower portions 71, 81 and 91 of the surrounding partitions 7, 8 and 9 are provided on the inorganic insulating layer 5.

The insulating layer 12 having this stepwise cross section can be formed by, for example, the following method.

Specifically, for example, an insulating layer is formed by using a positive organic material on the whole surface of the mother substrate 100 in which the insulating layer 111 is formed. Subsequently, the insulating layer is exposed to light. In this exposure process, the amount of exposure of the removed portion G is set so as to be the maximum value, and the amount of exposure is set so as to decrease in stages from the removed portion G toward the external side. Subsequently, the exposed insulating layer is developed. Subsequently, the insulating layer is baked.

By this process, the insulating layer 12 having the cross sectional shape described above is formed.

In this configuration example, when the mother substrate 100 is cut along the cut lines CL, the cross section of the display panel PNL along the C′-D′ line of FIG. 13 corresponds to the cross section of the area on the left side relative to the cut line CL in the mother substrate 100 shown in FIG. 16.

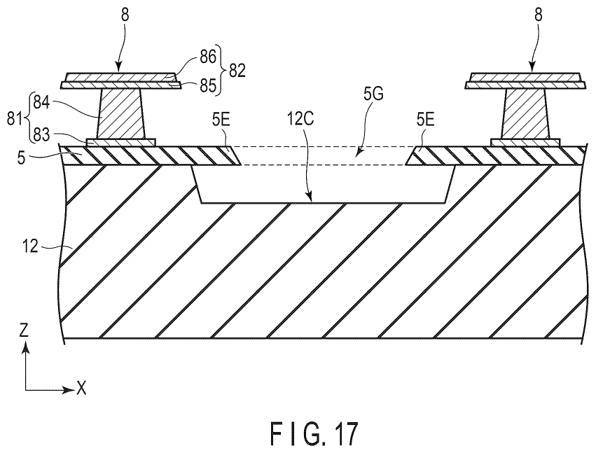

FIG. 17 is a cross-sectional view in which an area including the groove 5G is enlarged.

The insulating layer 12 has a recess portion 12C which overlaps the groove 5G. The recess portion 12C is enlarged relative to the groove 5G in a direction (in the example shown in the figure, the first direction X) orthogonal to the extension direction of the groove 5G. The inorganic insulating layer 5 has an edge portion 5E along the groove 5G. The edge portion 5E overlaps the recess portion 12C and is spaced apart from the insulating layer 12. In other words, the inorganic insulating layer 5 is formed into an overhang shape. The surrounding partitions 8 do not overlap the recess portion 12C or the edge portion 5E.

As described above, each surrounding partition 8 is formed into the overhang shape in a manner similar to that of the partition 6. In each surrounding partition 8, the lower portion 81 has a first conductive layer 83 provided on the inorganic insulating layer 5, and a second conductive layer 84 provided on the first conductive layer 83. For example, the first conductive layer 83 is formed so as to be thinner than the second conductive layer 84. In the example shown in the figure, the both end portions of the first conductive layer 83 protrude from the side surfaces of the second conductive layer 84.

The upper portion 82 has a first thin film 85 provided on the second conductive layer 84, and a second thin film 86 provided on the first thin film 85. The both end portions of the first thin film 85 and the second thin film 86 protrude from the side surfaces of the second conductive layer 84.

Since a pair of surrounding partitions 8 is provided on the both sides of the groove 5G, the inorganic insulating layer 5 is pressed against the insulating layer 12 by the surrounding partitions 8. This configuration can prevent the rise of the inorganic insulating layer 5 based on the edge portion 5E of the inorganic insulating layer 5, and the separation of the inorganic insulating layer 5 from the insulating layer 12.

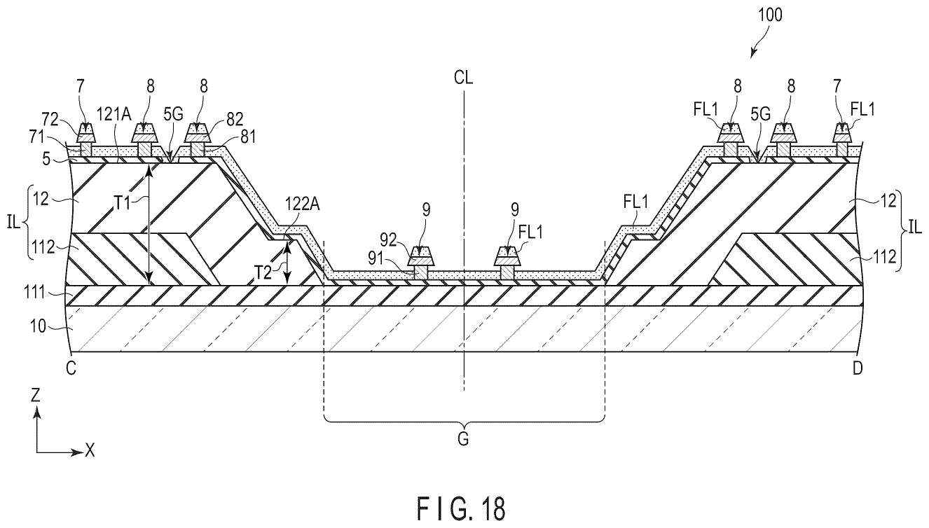

FIG. 18 is a cross-sectional view for explaining a state in which the stacked film FL1 is formed in an area including the removed portion G shown in FIG. 14.

For example, in the process of forming the display element DE1 described above, the stacked film FL1 is formed in the margin portion MP and the surrounding area SA in addition to the display area. Here, the stacked film FL1 includes, for example, the organic layer OR1, the upper electrode UE1 and the cap layer CP1 for forming the display element DE1. The stacked film FL1 is formed on the inorganic insulating layer 5 and the surrounding partitions 7, 8 and 9.

The stacked film FL1 is divided by the surrounding partitions 7, 8 and 9 having overhang shapes. The materials which are emitted from evaporation sources when the organic layer OR1, the upper electrode UE1 and the cap layer CP1 are formed by vapor deposition are blocked by the respective upper portions 72, 82 and 92 of the surrounding partitions 7, 8 and 9. Thus, each of the organic layer OR1, the upper electrode UE1 and the cap layer CP1 is partly stacked on the upper portions 72, 82 and 92. The organic layer OR1, the upper electrode UE1 and the cap layer CP1 located on the upper portions 72, 82 and 92 are spaced apart from the organic layer OR1, the upper electrode UE1 and the cap layer CP1 located on the inorganic insulating layer 5. By this configuration, the stacked film FL1 is partly divided.

Compared to a case where the stacked film FL1 is not divided by the surrounding partitions 7, 8 or 9, the area of the continuous stacked film FL1 is reduced, and a stress which could be generated in the stacked film FL1 is dispersed. Further, the inorganic insulating layer 5 and the stacked film FL1 are pressed by the surrounding partitions 7, 8 and 9. This configuration can prevent the rise of the inorganic insulating layer 5 from the insulating layer 12 and the rise of the stacked film FL1 from the inorganic insulating layer 5. In addition, when the sealing layer SE1 is formed on the stacked film FL1, the sealing layer SE1 presses the stacked film FL1 together with the surrounding partitions 7, 8 and 9. In this manner, the separation of the stacked film FL1 and the sealing layer SE1 from the inorganic insulating layer 5 can be prevented.

The organic insulating layer IL has a stepwise cross section in which the thickness decreases toward the removed portion G. Thus, the formation of a steep step is prevented. The elongation of the organic insulating layer IL is less as the thickness decreases. Thus, when the stacked film FL1 is formed on the organic insulating layer IL, the distortion of the stacked film FL1 is less, and the local concentration of stress can be prevented in the stacked film FL1. By this configuration, the separation of the stacked film FL1 from the inorganic insulating layer 5 can be prevented.

Here, this specification explains problems which could occur when the stacked film FL1 rises from the inorganic insulating layer 5 and is broken. The inorganic insulating layer 5 separated from the insulating layer 12 and the stacked film FL1 separated from the inorganic insulating layer 5 could float inside the manufacturing device as foreign substances and could be a contaminant source. If the floating foreign substances are attached to the processing substrate, various defects could be caused.

This embodiment can prevent the separation of the inorganic insulating layer 5 and the stacked film FL1. This configuration prevents the contamination of the manufacturing device and the generation of undesired foreign substances. In this manner, the reduction in reliability is prevented.

Even in a case where the stacked film FL1 is replaced by the stacked film FL2 which includes the organic layer OR2, the upper electrode UE2 and the cap layer CP2 for forming the display element DE2, similar effects are obtained.

Further, even in a case where the stacked film FL1 is replaced by the stacked film FL3 which includes the organic layer OR3, the upper electrode UE3 and the cap layer CP3 for forming the display element DE3, similar effects are obtained.

Here, the effect of preventing the separation of the inorganic insulating layer 5 and the stacked film FL1 is explained with respect to the configuration example shown in FIG. 14. In addition, similar effects are obtained regarding the other configuration examples.

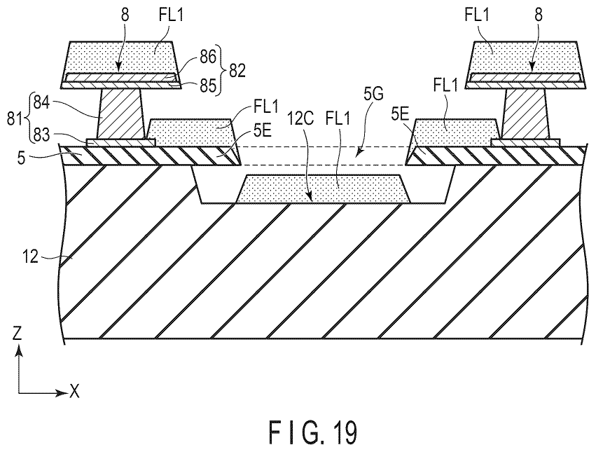

FIG. 19 is a cross-sectional view for explaining a state in which the stacked film FL1 is formed in an area including the groove 5G shown in FIG. 17.

The stacked film FL1 is formed on the inorganic insulating layer 5 and the surrounding partitions 8, and is further formed in the recess portion 12C of the insulating layer 12. The stacked film FL1 is divided by the inorganic insulating layer 5 and surrounding partitions 8 having overhang shapes. Thus, the stacked film FL1 formed on each surrounding partition 8 is spaced apart from the stacked film FL1 formed on the inorganic insulating layer 5. The stacked film FL1 formed on the inorganic insulating layer 5 is spaced apart from the stacked film FL1 formed in the recess portion 12C. In this manner, the stacked film FL1 is divided into the inner area surrounded by the loop groove 5G and the external area.

By this configuration, the stress generated in the stacked film FL1 is reduced, and effects similar to those explained with reference to FIG. 18 are obtained.

In addition, compared to a case where the groove 5G does not exist, the stacked film FL1 is divided. Therefore, the capacity of the stacked film FL1 is reduced. Thus, the electrostatic discharge from the stacked film FL1 is prevented. For this reason, the break of the stacked film FL1 and the surrounding portion caused by electrostatic discharge can be prevented. In this manner, the reduction in reliability is prevented.

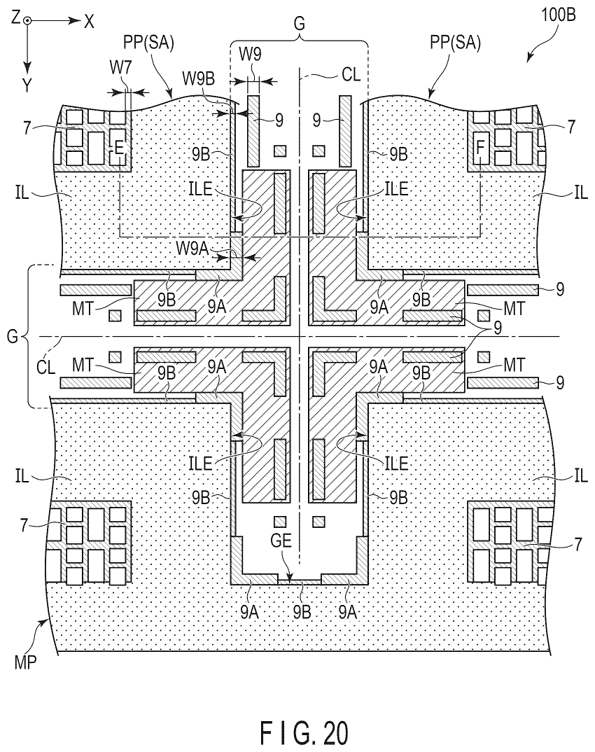

FIG. 20 is a plan view showing another configuration example of the area 100B shown in FIG. 11.

The configuration example shown in FIG. 20 is different from that shown in FIG. 12 in respect that the surrounding partitions 9 provided in the removed portion G include surrounding partitions (second partitions) 9A provided along the corner portions of the outer edges ILE of the organic insulating layer IL. Each of the corner portions of the outer edges ILE is substantially a right angle in plan view. Each surrounding partition 9A is formed into an L-shape in plan view.

In FIG. 20, the illustrations of the groove 5G of the inorganic insulating layer 5 and the surrounding partitions 8 are omitted.

In the example shown in the figure, conductive layers 9B are provided along the linear portions of the outer edges ILE. The conductive layers 9B are, for example, a residue generated in the process of forming the conductive surrounding partitions 7, 8 and 9. Thus, the conductive layers 9B do not necessarily exist.

In the example shown in the figure, the conductive layers 9B are connected to the surrounding partitions 9A. Width W9B of each conductive layer 9B is less than width W9A of each surrounding partition 9A in plan view. For example, width W9A is approximately 20 μm, and width W9B is several micrometers. Width W9B of each conductive layer 9B is less than width W9 of the other surrounding partitions 9. Width W9 is equal to width W9A. As described above, to prevent the loss of the surrounding partitions 9 or the formation failure of the surrounding partitions 9, width W9 and width W9A are greater than width W7 of each surrounding partition 7.

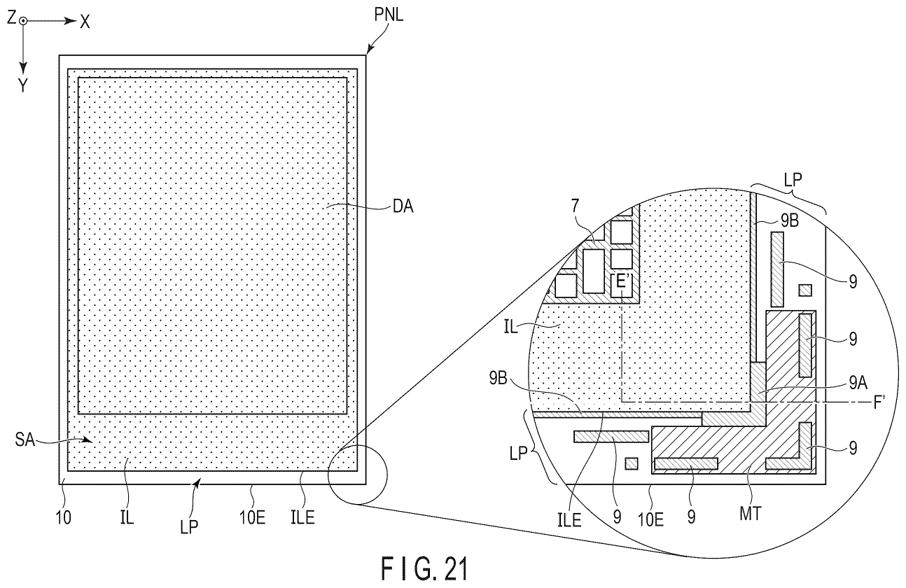

FIG. 21 is a plan view showing the display panel PNL cut out along the cut lines CL shown in FIG. 20.

When one corner portion of the substrate 10 is enlarged, part of the metal layers MT constituting the alignment marks shown in FIG. 20 and the surrounding partitions 9 and 9A are provided in the removed portion LP. In other words, the metal layer MT and the surrounding partitions 9 and 9A are located between the outer edge ILE and the outer edge 10E in plan view. The metal layer MT is formed into an L-shape along the corner portion of the substrate 10. Some of the surrounding partitions 9 overlapping the metal layer MT are linearly formed along the outer edge 10E. The surrounding partition 9A along the corner portion of the outer edge ILE is formed into an L-shape.

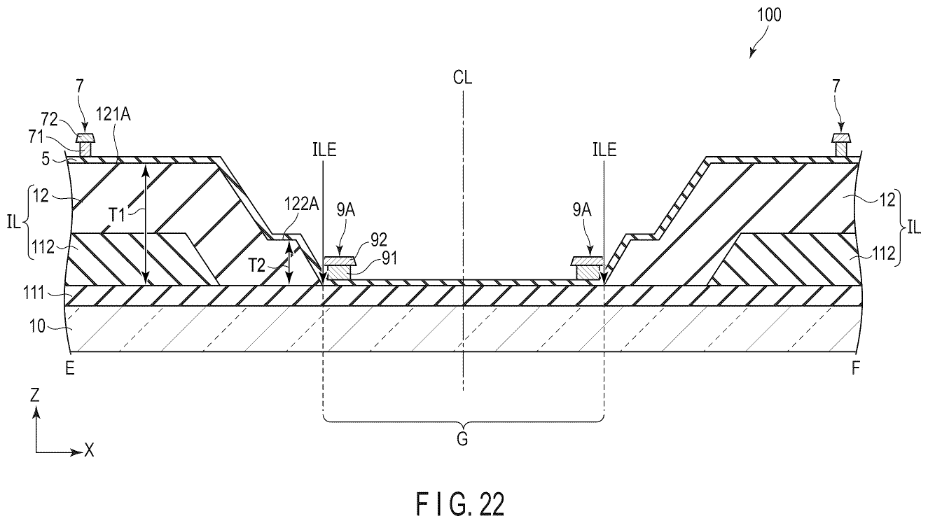

Now, this specification explains several configuration examples of the cross sectional structure of the mother substrate 100 along the E-F line of FIG. 20. In each of the cross-sectional views shown in FIG. 22 to FIG. 24, the illustrations of the groove 5G and the surrounding partitions 8 are omitted.

FIG. 22 is a cross-sectional view showing a configuration example of the mother substrate 100.

The configuration example shown in FIG. 22 is substantially the same as that shown in FIG. 14 excluding the structure in which the surrounding partitions 9A are provided along the outer edges ILE.

The insulating layer 111 is an inorganic insulating layer and is provided on the substrate 10. The insulating layer 112 is an organic insulating layer and is provided on the insulating layer 111. The insulating layer 12 is an organic insulating layer, covers the insulating layer 112 and has the removed portion G in the area which is in contact with the insulating layer 111. The organic insulating layer IL having the insulating layer 112 and the insulating layer 12 has a stepwise cross section in which the thickness decreases toward the removed portion G.

Each surrounding partition 9A has a lower portion 91 provided on the inorganic insulating layer 5 and an upper portion 92 provided on the lower portion 91. The upper portion 92 has a width which is greater than that of the lower portion 91. The both end portions of the upper portion 92 protrude relative to the side surfaces of the lower portion 91. Thus, the cross sectional shape of each surrounding partition 9A is the same as that of each surrounding partition 9 shown in FIG. 14. These surrounding partitions 9A can be also formed by the same process as the partition 6.

In this configuration example, when the mother substrate 100 is cut along the cut lines CL, the cross section of the display panel PNL along the E′-F′ line of FIG. 21 corresponds to the cross section of the area on the left side relative to the cut line CL in the mother substrate 100 shown in FIG. 22.

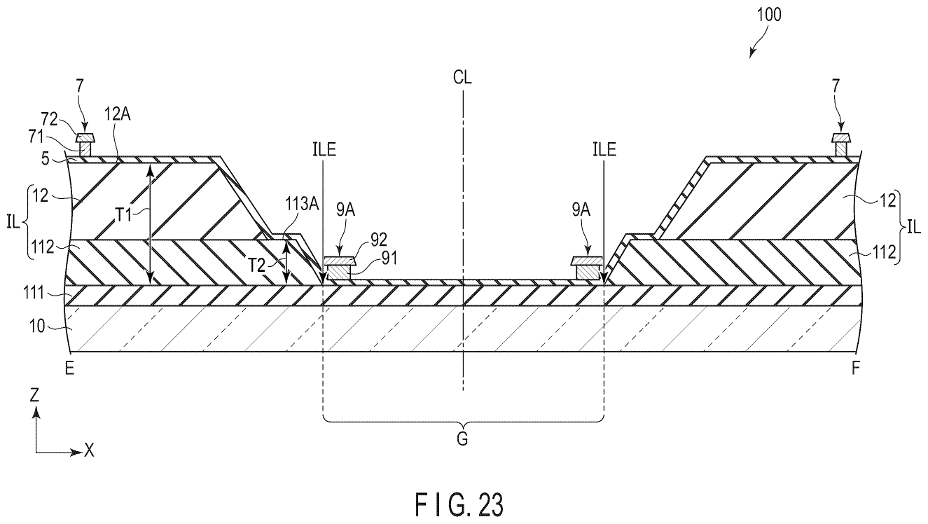

FIG. 23 is a cross-sectional view showing another configuration example of the mother substrate 100.

The configuration example shown in FIG. 23 is substantially the same as that shown in FIG. 15 excluding the structure in which the surrounding partitions 9A are provided along the outer edges ILE.

The insulating layer 112 extends toward the cut line CL relative to the insulating layer 12 and has the removed portion G. The insulating layer 12 is provided on the insulating layer 112. The organic insulating layer IL having the insulating layer 112 and the insulating layer 12 has a stepwise cross section in which the thickness decreases toward the removed portion G. The lower portion 91 of each surrounding partition 9A is provided on the inorganic insulating layer 5.

In this configuration example, when the mother substrate 100 is cut along the cut lines CL, the cross section of the display panel PNL along the E′-F′ line of FIG. 21 corresponds to the cross section of the area on the left side relative to the cut line CL in the mother substrate 100 shown in FIG. 23.

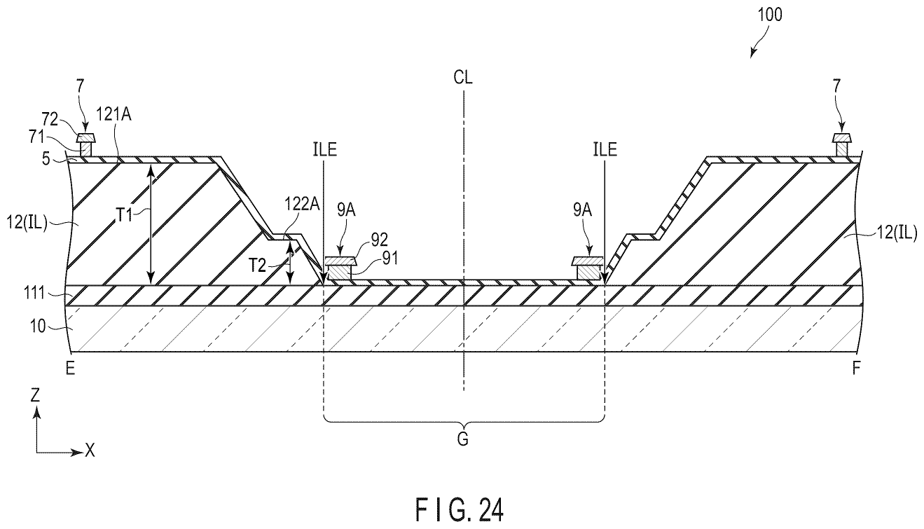

FIG. 24 is a cross-sectional view showing another configuration example of the mother substrate 100.

The configuration example shown in FIG. 24 is substantially the same as that shown in FIG. 16 excluding the structure in which the surrounding partitions 9A are provided along the outer edges ILE.

The insulating layer 12 is provided on the insulating layer 111 and has the removed portion G. The organic insulating layer IL is a single-layer body of the insulating layer 12. The insulating layer 112 does not exist. When this specification focuses attention on the cross sectional shape of the organic insulating layer IL, the organic insulating layer IL has a stepwise cross section in which the thickness decreases toward the removed portion G. The lower portion 91 of each surrounding partition 9A is provided on the inorganic insulating layer 5.

In this configuration example, when the mother substrate 100 is cut along the cut lines CL, the cross section of the display panel PNL along the E′-F′ line of FIG. 21 corresponds to the cross section of the area on the left side relative to the cut line CL in the mother substrate 100 shown in FIG. 24.

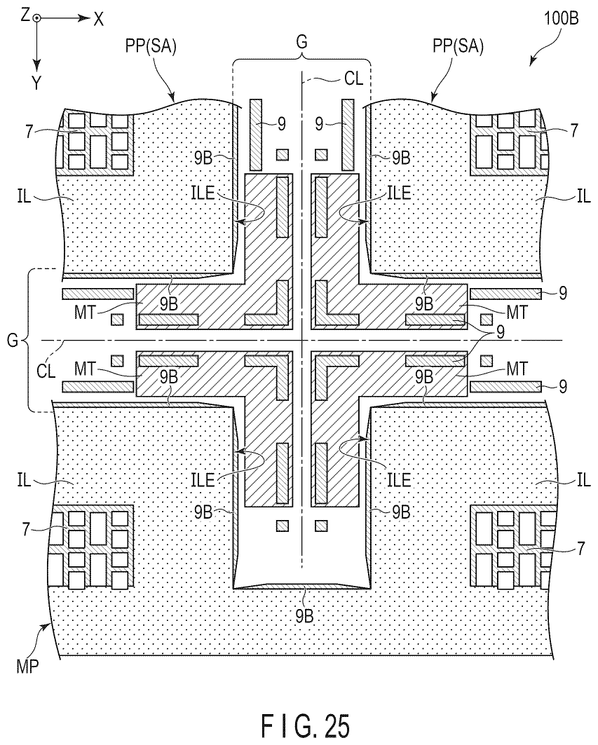

FIG. 25 is a diagram for explaining problems which could occur when the surrounding partitions 9A are not provided.

In a case where the conductive layers 9B are formed along the outer edges ILE as a residue which is generated in the process of forming the surrounding partitions, the conductive layers 9B tend to taper toward the corner portions of the outer edges ILE. At this time, charge is easily concentrated on the sharp end of each conductive layer 9B. Thus, electrostatic discharge may be induced between the adjacent conductive layers 9B or between each conductive layer 9B and the surrounding portion. Further, electrostatic discharge may be induced between the stacked film FL1 and each conductive layer 9B when the stacked film FL1 is formed in the subsequent process.

To the contrary, in the configuration example shown in FIG. 20, as the surrounding partitions 9A are intentionally provided in the corner portions of the outer edges ILE, even if the conductive layers 9B are formed, the conductive layers 9B are connected to the surrounding partitions 9A, and thus, sharp ends are not easily formed. Thus, electrostatic discharge based on the conductive layers 9B is prevented. This configuration can prevent the break of the surrounding portions of the conductive layers 9B and the stacked film FL1 caused by electrostatic discharge. In this manner, the reduction in reliability is prevented.

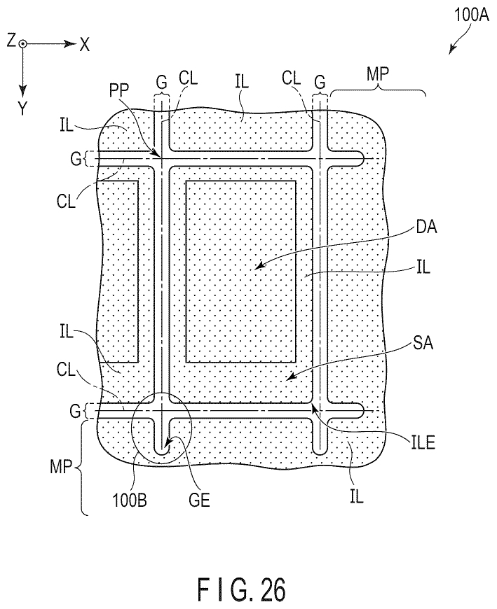

FIG. 26 is a plan view showing another configuration example of the area 100A of the mother substrate 100 shown in FIG. 10.

The configuration example shown in FIG. 26 is different from that shown in FIG. 11 in respect that the outer edges ILE of the organic insulating layer IL include round corner portions. Here, each round corner portion corresponds to a portion which is formed into an arcuate shape in the outer edge ILE of the organic insulating layer IL in plan view. In the example shown in the figure, the round corner portions are formed near the intersections of the cut lines CL in the surrounding area SA of the panel portion PP. In the margin portion MP, the round corner portions are formed near the intersections of the cut lines CL and in the end portions GE of the removed portion G.

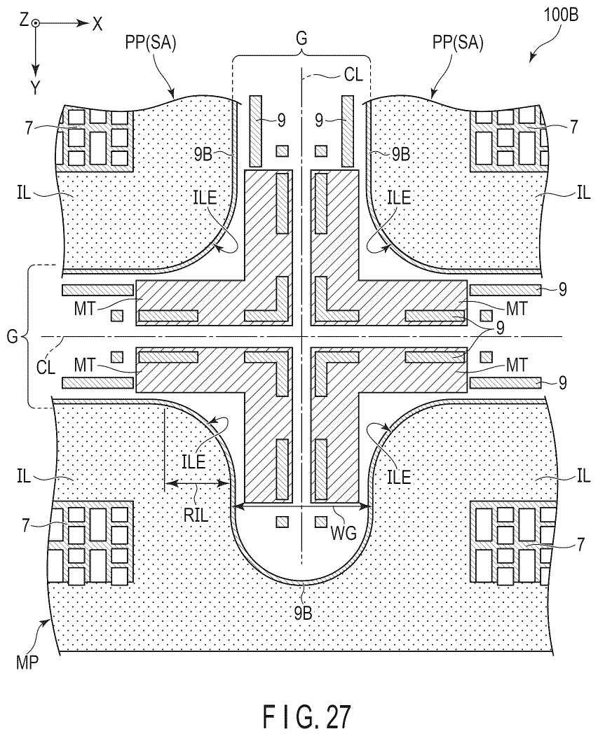

FIG. 27 is a plan view showing a configuration example of the area 100B shown in FIG. 26. In FIG. 27, the illustrations of the groove 5G of the inorganic insulating layer 5 and the surrounding partitions 8 are omitted.

Each of the round corner portions of the outer edges ILE of the organic insulating layer IL is formed into an arcuate shape having radius of curvature RIL. Radius of curvature RIL is, for example, greater than or equal to ½ of width WG (WG/2<RIL). Width WG is the width of the removed portion G extending in the second direction Y and is parallel to the first direction X. For example, radius of curvature RIL is greater than or equal to 150 μm.

In the example shown in the figure, each conductive layer 9B is provided along the outer edge ILE including the round corner portion. Each conductive layer 9B has substantially a constant width. These conductive layers 9B are a residue which is generated in the process of forming the conductive surrounding partitions 7, 8 and 9 as described above, and do not necessarily exist.

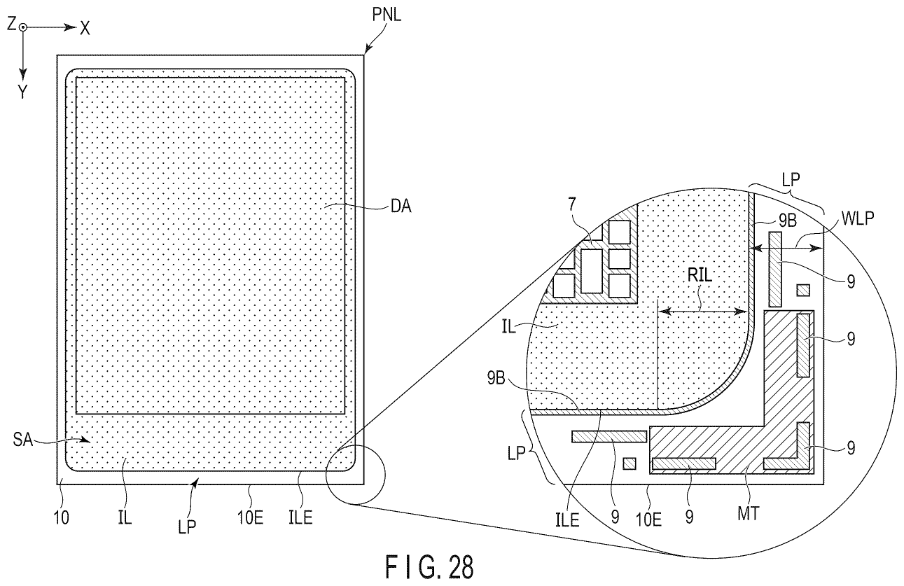

FIG. 28 is a plan view showing the display panel PNL cut out along the cut lines CL shown in FIG. 27.

When one corner portion of the substrate 10 is enlarged, part of the metal layers MT constituting the alignment marks shown in FIG. 27 and the surrounding partitions 9 are provided in the removed portion LP. The metal layer MT is formed into an L-shape along the corner portion of the substrate 10. Some of the surrounding partitions 9 overlapping the metal layer MT are linearly formed along the outer edge 10E. The corner portion of the outer edge ILE is made round. The conductive layer 9B is provided along the outer edge ILE.

The round corner portion of the outer edge ILE is formed into an arcuate shape having radius of curvature RIL. Radius of curvature RIL is, for example, greater than or equal to width WLP (WLP≤RIL). Width WLP is the width of the removed portion LP extending in the second direction Y and is parallel to the first direction X.

Since the corner portion of the outer edge ILE is made round in this manner, even if the conductive layer 9B is formed, the conductive layer 9B has substantially a constant width along the outer edge ILE, and thus, a sharp end is not easily formed. Thus, electrostatic discharge based on the conductive layer 9B is prevented. This configuration can prevent the break of the surrounding portion of the conductive layer 9B and the stacked film FL1 caused by electrostatic discharge.

Radius of curvature RIL of each round corner portion is greater than or equal to ½ of width WG of the removed portion G in the mother substrate 100 or greater than or equal to width WLP of the removed portion LP in the display panel PNL. This configuration can prevent the rise or separation of the stacked film FL1 or the inorganic insulating layer 5 based on the vicinity of each corner portion. In this manner, the reduction in reliability is prevented.

In the above embodiment, for example, in the surrounding partitions 7, 8 and 9, the lower portions 71, 81 and 91 correspond to first lower portions, and the upper portions 72, 82 and 92 correspond to first upper portions. The surrounding partitions 8 correspond to first partitions. The surrounding partitions 9 and 9A corresponds to second partitions. In the partition 6, the lower portion 61 corresponds to a second lower portion, and the upper portion 62 corresponds to a second upper portion. In the organic insulating layer IL, the insulating layer 112 corresponds to a first layer, and the insulating layer 12 corresponds to a second layer. In the inorganic insulating layer 5, the groove 5G corresponds to a first groove, and a groove 5GA corresponds to a second groove.

As explained above, the present embodiment can provide a display device and a mother substrate such that the reduction in reliability can be prevented.

All of the display devices and the mother substrates that can be implemented by a person of ordinary skill in the art through arbitrary design changes to the display device and the mother substrate described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

Examples of the display device and the mother substrate obtained from the configuration disclosed in this specification are additionally described below.
(1)

A display device comprising:
a substrate;
an organic insulating layer provided over a display area which displays an image and a surrounding area on an external side relative to the display area above the substrate;
a lower electrode provided on the organic insulating layer in the display area;
an inorganic insulating layer which is provided on the organic insulating layer and covers a peripheral portion of the lower electrode;
an organic layer which is provided on the lower electrode and includes a light emitting layer;
an upper electrode provided on the organic layer; and
a plurality of surrounding partitions provided in the surrounding area, wherein
each of the surrounding partitions has a first lower portion, and a first upper portion located on the first lower portion and protruding from a side surface of the first lower portion,
the organic insulating layer has a removed portion along an outer edge of the substrate in the surrounding area,
the surrounding partitions include a second partition provided in the removed portion, and
the second partition is provided along a corner portion in an outer edge of the organic insulating layer and is formed into an L-shape in plan view.
(2)

The display device of (1), further comprising
a conductive layer provided along a linear portion in the outer edge of the organic insulating layer, wherein
the conductive layer is connected to the second partition, and
a width of the conductive layer is less than a width of the second partition.
(3)

A display device comprising:
a substrate;
an organic insulating layer provided over a display area which displays an image and a surrounding area on an external side relative to the display area above the substrate;
a lower electrode provided on the organic insulating layer in the display area;
an inorganic insulating layer which is provided on the organic insulating layer and covers a peripheral portion of the lower electrode;
an organic layer which is provided on the lower electrode and includes a light emitting layer;
an upper electrode provided on the organic layer; and
a plurality of surrounding partitions provided in the surrounding area, wherein
each of the surrounding partitions has a first lower portion, and a first upper portion located on the first lower portion and protruding from a side surface of the first lower portion,
the organic insulating layer has a removed portion along an outer edge of the substrate in the surrounding area,
an outer edge of the organic insulating layer includes a round corner portion, and
a radius of curvature of the round corner portion is greater than or equal to a width of the removed portion.
(4)

The display device of (3), further comprising
a conductive layer provided along the outer edge of the organic insulating layer.
(5)

A mother substrate comprising:
a panel portion which has a display area displaying an image, and a surrounding area on an external side relative to the display area;
a margin portion on an external side relative to the panel portion;
an organic insulating layer provided over the panel portion and the margin portion;
a lower electrode provided on the organic insulating layer in the display area;
an inorganic insulating layer which is provided on the organic insulating layer and covers a peripheral portion of the lower electrode;
an organic layer which is provided on the lower electrode and includes a light emitting layer;
an upper electrode provided on the organic layer; and
a plurality of surrounding partitions provided in the surrounding area, wherein
each of the surrounding partitions has a first lower portion located on the inorganic insulating layer and a first upper portion located on the first lower portion and protruding from a side surface of the first lower portion,
the organic insulating layer has a removed portion along an outer shape of the panel portion,
the surrounding partitions include a second partition provided in the removed portion, and
the second partition is provided along a corner portion in an outer edge of the organic insulating layer and is formed into an L-shape in plan view.
(6)

A mother substrate comprising:
a panel portion which has a display area displaying an image, and a surrounding area on an external side relative to the display area;
a margin portion on an external side relative to the panel portion;
an organic insulating layer provided over the panel portion and the margin portion;
a lower electrode provided on the organic insulating layer in the display area;
an inorganic insulating layer which is provided on the organic insulating layer and covers a peripheral portion of the lower electrode;
an organic layer which is provided on the lower electrode and includes a light emitting layer;
an upper electrode provided on the organic layer; and
a plurality of surrounding partitions provided in the surrounding area, wherein
each of the surrounding partitions has a first lower portion located on the inorganic insulating layer and a first upper portion located on the first lower portion and protruding from a side surface of the first lower portion,
the organic insulating layer has a removed portion along an outer shape of the panel portion,
an outer edge of the organic insulating layer includes a round corner portion, and
a radius of curvature of the round corner portion is greater than or equal to ½ of a width of the removed portion.

What is claimed is:

1. A display device comprising:
a substrate;
an organic insulating layer provided over a display area which displays an image and a surrounding area on an external side relative to the display area above the substrate;
a lower electrode provided on the organic insulating layer in the display area;
an inorganic insulating layer which is provided on the organic insulating layer and covers a peripheral portion of the lower electrode;
an organic layer which is provided on the lower electrode and includes a light emitting layer;
an upper electrode provided on the organic layer; and
a plurality of surrounding partitions provided in the surrounding area, wherein
each of the surrounding partitions has a first lower portion located on the inorganic insulating layer, and a first upper portion located on the first lower portion and protruding from a side surface of the first lower portion,
the organic insulating layer has a removed portion along an outer edge of the substrate in the surrounding area,
the inorganic insulating layer has a groove surrounding the display area and formed into a loop shape in the surrounding area, and
the surrounding partitions include a pair of first partitions facing each other across the groove.

2. The display device of claim 1, wherein
the organic insulating layer has a recess portion which overlaps the groove, and
an edge portion of the inorganic insulating layer along the groove overlaps the recess portion and is spaced apart from the organic insulating layer.

3. The display device of claim 1, wherein
the inorganic insulating layer is provided in the removed portion, and
the surrounding partitions include a second partition provided on the inorganic insulating layer in the removed portion.

4. The display device of claim 3, wherein
the second partition is provided along a corner portion in an outer edge of the organic insulating layer and is formed into an L-shape in plan view.

5. The display device of claim 4, further comprising
a conductive layer provided along a linear portion in the outer edge of the organic insulating layer, wherein
the conductive layer is connected to the second partition, and
a width of the conductive layer is less than a width of the second partition.

6. The display device of claim 1, wherein
an outer edge of the organic insulating layer includes a round corner portion, and
a radius of curvature of the round corner portion is greater than or equal to a width of the removed portion.

7. The display device of claim 6, further comprising
a conductive layer provided along the outer edge of the organic insulating layer.

8. The display device of claim 1, further comprising
a partition which has a second lower portion provided on the inorganic insulating layer in the display area and formed of a conductive material, and a second upper portion provided on the second lower portion and protruding from a side surface of the second lower portion, wherein
the lower electrode, the organic layer and the upper electrode are surrounded by the partition, and
the upper electrode is in contact with the second lower portion of the partition.

9. The display device of claim 1, wherein
the organic insulating layer has a first layer and a second layer covering the first layer, and further has a stepwise cross section in which a thickness decreases toward the removed portion.

10. The display device of claim 1, wherein
the organic insulating layer has a first layer and a second layer provided on the first layer and exposing the first layer close to the removed portion, and further has a stepwise cross section in which a thickness decreases toward the removed portion.

11. The display device of claim 1, wherein
the organic insulating layer is a single-layer body and has a stepwise cross section in which a thickness decreases toward the removed portion.

12. A mother substrate comprising:
a panel portion which has a display area displaying an image, and a surrounding area on an external side relative to the display area;
a margin portion on an external side relative to the panel portion;
an organic insulating layer provided over the panel portion and the margin portion;
a lower electrode provided on the organic insulating layer in the display area;
an inorganic insulating layer which is provided on the organic insulating layer and covers a peripheral portion of the lower electrode;
an organic layer which is provided on the lower electrode and includes a light emitting layer;
an upper electrode provided on the organic layer; and
a plurality of surrounding partitions provided in the surrounding area, wherein
each of the surrounding partitions has a first lower portion located on the inorganic insulating layer, and a first upper portion located on the first lower portion and protruding from a side surface of the first lower portion,
the inorganic insulating layer has a first groove surrounding the display area and formed into a loop shape in the surrounding area, and
the surrounding partitions include a pair of first partitions facing each other across the first groove.

13. The mother substrate of claim 12, wherein
the organic insulating layer has a recess portion which overlaps the first groove, and
an edge portion of the inorganic insulating layer along the first groove overlaps the recess portion and is spaced apart from the organic insulating layer.

14. The mother substrate of claim 12, wherein
the organic insulating layer has a removed portion along an outer shape of the panel portion,
the removed portion has an end portion located in the margin portion, and
the inorganic insulating layer has a second groove which surrounds the end portion in the margin portion.
